(19) United States
(12) Patent Application Publication
(10) Pub. No.: US 2010/0190282 A1
(43) Pub. Date: Jul. 29, 2010

(54) METHOD FOR MANUFACTURING MULTIPLE-WAVELENGTH SEMICONDUCTOR LASER

(75) Inventors: Yasuaki Yoshida, Tokyo (JP); Hitoshi Sakuma, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/469,755

(22) Filed: May 21, 2009

(30) Foreign Application Priority Data
Jan. 23, 2009 (JP) 2009-012995

(51) Int. Cl. H01L 21/00

(52) U.S. Cl. 438/33; 257/E21.002; 438/35

(57) ABSTRACT

A method for manufacturing a multiple-wavelength semiconductor laser comprises: forming a first bar having an array of first semiconductor chips, wherein at least two semiconductor lasers producing light of different wavelengths are monolithically formed; forming a second bar having an array of second semiconductor chips, wherein a semiconductor laser producing light having a different wavelength from the light produced by the semiconductor lasers of the first semiconductor chips is formed; forming a third bar by locating a laser-forming surface of said first bar facing a back surface of the second bar, and joining respective first semiconductor chips in the first bar to respective second semiconductor chips in the second bar; forming scribe lines by irradiating boundaries of the first semiconductor chips and boundaries of the second semiconductor chips with laser beams, and dividing the third bar along the scribe lines into respective chips.

### BACKGROUND OF THE INVENTION

1. Field of the Invention

The present invention relates to a method for manufacturing a multiple-wavelength semiconductor laser wherein two semiconductor lasers having different wavelengths are joined, and specifically, to a method for manufacturing a multiple-wavelength semiconductor laser that can accurately align two semiconductor lasers and can secure high reliability.

2. Background Art

Recently, optical disks including CDs, DVDs, and Blu-ray disks (BDs) are extensively used as mass storage media. The oscillation wavelengths of semiconductor lasers used in these optical disk devices become shorter in the order of CDs, DVDs, and BDs depending on the storage capacities. The oscillation wavelength of the laser for CDs is 780 nm band (infrared semiconductor laser), the oscillation wavelength of the laser for DVDs is 650 nm band (red semiconductor laser), and the oscillation wavelength of the laser for BDs is 400 nm band (blue semiconductor laser). For processing information from CDs, DVDs, and BDs in an optical disk device, three beam sources: an infrared semiconductor laser, a red semiconductor laser, and a blue semiconductor laser are required.

In recent years, a two-wavelength semiconductor laser wherein an infrared semiconductor laser and a red semiconductor laser are monolithically formed in a semiconductor chip has been developed and becoming popular for downsizing and weight saving of the optical pickup device that constitutes an optical disk device. Furthermore, to correspond to BDs, a three-wavelength semiconductor laser, wherein a blue semiconductor laser and a two-wavelength semiconductor laser are combined, is being developed.

The three-wavelength semiconductor laser is manufactured by stacking and joining a two-wavelength semiconductor laser and a blue semiconductor laser (for example, refer to FIG. 1 of Patent Document 1). However, there was a problem wherein the alignment of the two-wavelength semiconductor laser and a blue semiconductor laser in joining was difficult.

To solve the problem, a method for dividing the two semiconductor lasers into chips using a cutting saw after joining them in a bar state is proposed (for example, refer to FIG. 1 of Patent Document 2). By this method, two semiconductor lasers can be aligned at high accuracy. In Patent Document 2, however, although the joining of the bar of the single wavelength semiconductor laser is described, the joining of the bar of the two-wavelength semiconductor laser is not described.
[Patent Document 1] Japanese Patent No. 3486900
[Patent Document 2] Japanese Patent Application Laid-Open No. 2002-232061

### SUMMARY OF THE INVENTION

In the two-wavelength semiconductor laser, an infrared semiconductor laser and a red semiconductor laser are lined up on a substrate. Therefore, if the laser forming surface of the bar of the two-wavelength semiconductor laser is allowed to face the bar of the blue semiconductor laser, a large gap is produced in the joint of the bars. Therefore, when the chips are divided using a cutting saw as described in Patent Document 2, since a large force is applied to the floating bar, the cracking of the chip or the peeling of the solder portion occurs. Even in a method for dividing after the bar is scratched using a needle-like scriber, since a high pressure is applied to the bar, the similar problem occurs.

When a cutting saw is used, the chip must be cut while cooling the chip and the saw with water. Therefore, moisture invades in the gap in the joint between the bars after chip dividing, causing a problem wherein the dew point is not lowered after packaging. Also when a cutting saw is used, chips produced by chip dividing fly and adhere to the electrode or the end surface of the laser to produce dirt or scratches.

Therefore, since the problem as described above was caused when the method according to Patent Document 2 was used to manufacture the three-wavelength semiconductor laser according to Patent Document 1, there was a problem wherein high reliability cannot be secured.

To solve the problems as described above, it is an object of the present invention to provide a method for manufacturing a multiple-wavelength semiconductor laser that can accurately align two semiconductor lasers and can secure high reliability.

According to one aspect of the present invention, a method for manufacturing a multiple-wavelength semiconductor laser comprises: forming a first bar having a plurality of arrayed first semiconductor chips wherein at least two semiconductor lasers of different wavelengths are monolithically formed; forming a second bar having a plurality of arrayed second semiconductor chips wherein a semiconductor laser having a different wavelength from the semiconductor lasers of said first semiconductor chips is formed; forming a third bar by allowing a laser-forming surface of said first bar to face a back surface of said second bar, and joining respective said first semiconductor chips in said first bar to respective said second semiconductor chips in said second bar; forming scribe lines by radiating laser beams on boundaries of said first semiconductor chips and on boundaries of said second semiconductor chips, respectively and dividing said third bar along said scribe lines into each chip.

Other and further objects, features and advantages of the invention will appear more fully from the following description.

### BRIEF DESCRIPTION OF THE DRAWINGS

FIG. 1 is a sectional view showing a multiple-wavelength semiconductor laser according to the first embodiment.

FIGS. 2-16 are views for explaining a method of manufacturing the multiple-wavelength semiconductor laser according to the first embodiment.

FIGS. 17-18 are views for explaining a method of manufacturing a multiple-wavelength semiconductor laser according to the second embodiment.

FIG. 19 is a view for explaining a method of manufacturing a multiple-wavelength semiconductor laser according to the third embodiment.

FIG. 20 is a view for explaining a method of manufacturing a multiple-wavelength semiconductor laser according to the fourth embodiment.

FIG. 21 is a view for explaining a method of manufacturing a multiple-wavelength semiconductor laser according to the fifth embodiment.

### DETAILED DESCRIPTION OF THE PREFERRED EMBODIMENTS

### First Embodiment

### Structure of Multiple-Wavelength Semiconductor Laser According to First Embodiment

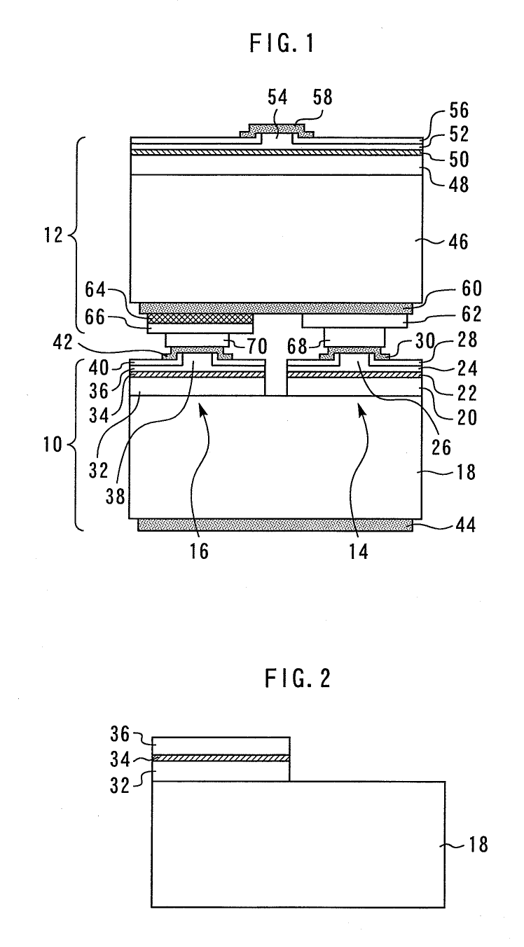

FIG. 1 is a sectional view showing a multiple-wavelength semiconductor laser according to the first embodiment. The multiple-wavelength semiconductor laser is a three-wavelength semiconductor laser formed by joining a two-wavelength semiconductor laser 10 and a blue semiconductor laser 12. The two-wavelength semiconductor laser 10 is a semiconductor laser wherein a red semiconductor laser 14 and an infrared semiconductor laser 16 are monolithically formed.

The red semiconductor laser 14 is an AlGaInP-based semiconductor laser. An n-type AlGaInP clad layer 20, an active layer 22 having an InGaP/AlGaInP multiple quantum well structure, and a p-type AlGaInP clad layer 24 are sequentially formed on a GaAs substrate 18. A ridge 26 is formed on the p-type AlGaInP clad layer 24. An insulating film 28 is formed on the sides of the ridge 26 and on the p-type AlGaInP clad layer 24 on the both sides of the ridge 26. A p-electrode 30 is formed on the ridge 26.

The infrared semiconductor laser 16 is an AlGaAs semiconductor laser. An n-type AlGaAs clad layer 32, an active layer 34 having an AlGaAs/AlGaAs multiple quantum well structure, and a p-type AlGaAs clad layer 36 are sequentially formed on the GaAs substrate 18. A ridge 38 is formed on the p-type AlGaAs clad layer 36. An insulating film 40 is formed on the sides of the ridge 38 and on the p-type AlGaAs clad layer 36 on the both sides of the ridge 38. A p-electrode 42 is formed on the ridge 38. An n-electrode 44 common to the red semiconductor laser 14 and the infrared semiconductor laser 16 is formed on the back surface of the GaAs substrate 18.

The blue semiconductor laser 12 is a gallium-nitride-based semiconductor laser. An n-type AlGaN clad layer 48, an active layer 50 having an undoped InₓGa₁₋ₓN/In_{y}Ga_{1-y}N multiple quantum well structure, and a p-type AlGaN clad layer 52 are sequentially formed on a GaN substrate 46. A ridge 54 is formed on the p-type AlGaN clad layer 52. An insulating film 56 is formed on the sides of the ridge 54 and on the p-type AlGaN clad layer 52 on the both sides of the ridge 54. A P-electrode 58 is formed on the ride 54 and an n-electrode 60 is formed on the back surface of the GaN substrate 46.

On the n-electrode 60 on the back surface of the substrate of the blue semiconductor laser 12, a first electrode 62 is directly formed on the red semiconductor laser 14 side, and a second electrode 66 is formed via an insulating layer 64 on the infrared semiconductor laser 16 side. The p-electrode 30 of the red semiconductor laser 14 is joined to the first electrode 62 via a solder 68, and the p-electrode 42 of the infrared semiconductor laser 16 is joined to the second electrode 66 via a solder 70. Contrary to this example, the first electrode 62 may be formed via the insulating layer 64 on the red semiconductor laser 14 side, and the second electrode 66 may be directly formed on the infrared semiconductor laser 16 side.

The three-wavelength semiconductor laser, wherein the blue semiconductor laser 12 is joined to the two-wavelength semiconductor laser 10, is die-bonded to a sub-mount with the p-electrode 58 side of the blue semiconductor laser 12 facing down, and is mounted to a package (not shown). The first electrode 62, the second electrode 66, and the n-electrode 44 are wire-bonded to the electrode pins of the package. The p-electrode 58 is wire-bonded to the electrode pins of the package via a metal layer on the sub-mount (not shown).

To the blue semiconductor laser 12, a driving current is supplied via the bonding wires of the p-electrode 58 and the first electrode 62. To the red semiconductor laser 14, the driving current is supplied via the bonding wires of the first electrode 62 and the n-electrode 44. To the infrared semiconductor laser 16, the driving current is supplied via the bonding wires of the second electrode 66 and the n-electrode 44.

### Method for Manufacturing Multiple-Wavelength Semiconductor Laser According to First Embodiment

A method for manufacturing a multiple-wavelength semiconductor laser according to the first embodiment will be described.

### Manufacture of Two-Wavelength Semiconductor Laser

First, as shown in FIG. 2, an n-type AlGaAs clad layer 32, an active layer 34 having an AlGaAs/AlGaAs multiple quantum well structure, and a p-type AlGaAs clad layer 36 are sequentially formed using metal organic chemical vapor deposition (MOCVD) on a GaAs substrate 18 whose surface is previously cleaned by thermal cleaning or the like. Next, a resist is applied on the entire surface of the wafer, and a resist pattern (not shown) of a shape corresponding to the left half of the drawing is formed by lithography. The right half of the stacked layers shown in the drawing is etched off using the resist pattern as a mask.

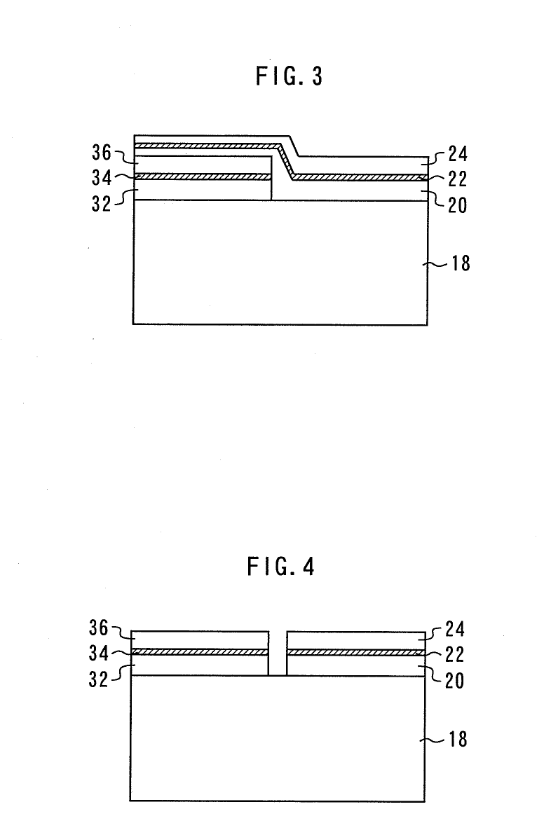

Next, as shown in FIG. 3, an n-type AlGaInP clad layer 20, an active layer 22 having an InGaP/AlGaInP multiple quantum well structure, and a p-type AlGaInP clad layer 24 are sequentially formed using the MOCVD method on the GaAs substrate 18.

Next, a resist is applied on the entire surface of the wafer, and a resist pattern (not shown) of a shape corresponding to the right half of the drawing is formed by lithography. The left half of the stacked n-type AlGaInP clad layer 20, the active layer 22, and the p-type AlGaInP clad layer 24 as shown in FIG. 4 is etched off using the resist pattern as a mask.

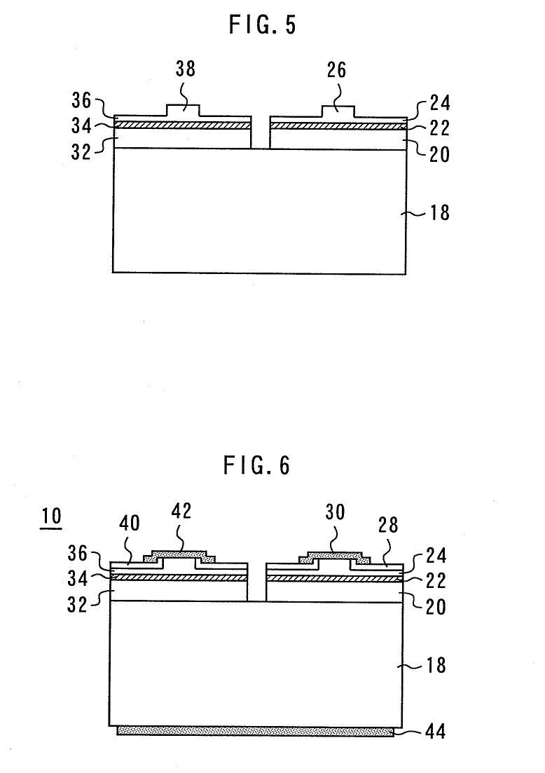

Next, a resist is applied on the entire surface of the wafer, and a resist pattern (not shown) of a shape corresponding to the shape of the mesa portion is formed by lithography. The p-type AlGaAs clad layer 36 and the p-type AlGaInP clad layer 24 are etched by RIE using the resist pattern as a mask. Thereby, as shown in FIG. 5, ridges 26 and 38 to be a light waveguide structure are formed.

Next, leaving the resist pattern (not shown) used as the mask, an insulating film composed of SiO₂ is formed on the entire surface of the substrate by, for example, CVD, vacuum vapor deposition, or sputtering, and the insulating films on the ridges 26 and 38 are removed, or lift off, at the same time of resist removal. Thereby, as shown in FIG. 6, insulating films 28 and 40 each having an opening are formed on the ridges 26 and 38.

Next, after sequentially forming a Ti film and an Au film on the entire surface of the wafer by, for example, vacuum vapor deposition, resist application, lithography, and wet etching or dry etching are performed to form the p-electrode 30 of the red semiconductor laser 14 and the p-electrode 42 of the infrared semiconductor laser 16 on the laser forming surface of the two-wavelength semiconductor laser 10. Next, AuGe and Au films are sequentially formed in the back surface of the substrate by vacuum vapor deposition to form the n-electrode 44.

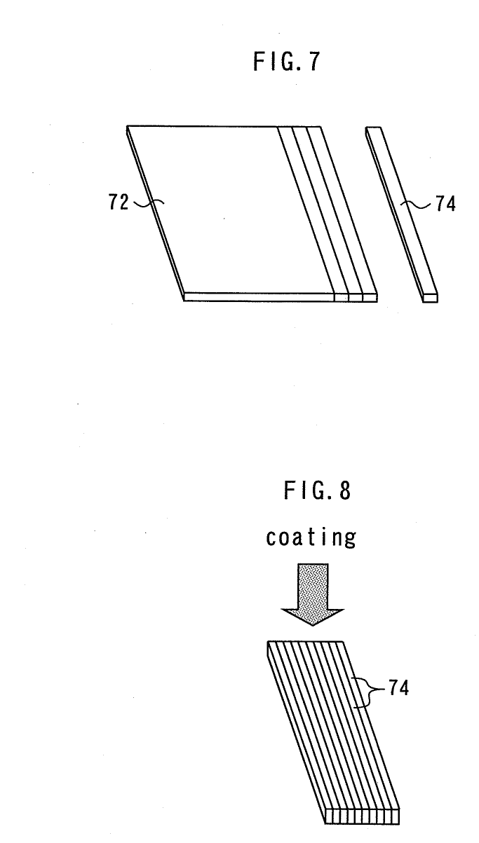

Through the above-described wafer processing, semiconductor chips (first semiconductor chips), wherein two-wavelength semiconductor lasers 10 having red semiconductor lasers 14 and infrared semiconductor lasers 16 having different wavelengths are formed in lines on the wafer 72, are formed. Next, as shown in FIG. 7, the wafer 72 is divided by cleaving to form first bars 74 wherein a plurality of semiconductor chips of the two-wavelength semiconductor lasers 10 are arrayed. By cleaving, the end surfaces of the laser having no cracks and steps can be formed.

Next, as shown in FIG. 8, a plurality of the first bars 74 are fixed by a jig and placed in a vacuum apparatus with the end surfaces of the laser turned up. Then, coating films are formed on the front and rear ends of the laser by vacuum vapor deposition or sputtering.

### Manufacture of Blue Semiconductor Laser

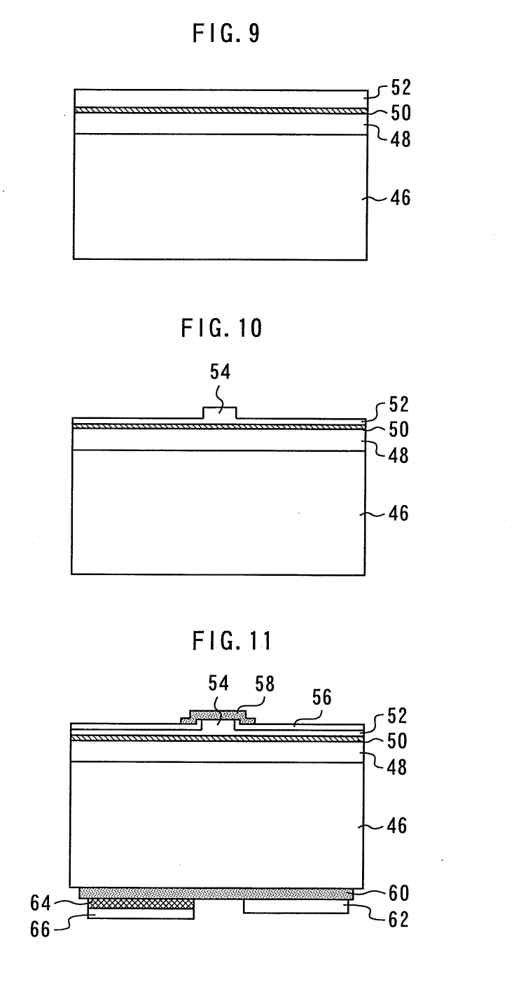

First, as shown in FIG. 9, an n-type AlGaN clad layer 48, an active layer 50 having an undoped InₓGa₁₋ₓN/In_{y}Ga_{1-y}N multiple quantum well structure, and a p-type AlGaN clad layer 52 are sequentially formed on a GaN substrate 46 whose surface is previously cleaned by thermal cleaning or the like by the MOCVD method. For example, the growing temperature of the n-type AlGaN clad layer 48 is 1000° C., the growing temperature of the active layer 50 is 740° C., and the growing temperature of the p-type AlGaN clad layer 52 is 1000° C.

Next, a resist is applied on the entire surface of the wafer, and a resist pattern (not shown) of a shape corresponding to the shape of the mesa portion is formed by lithography. The p-type AlGaN clad layer 52 is etched by, for example, RIE using the resist pattern as a mask. Thereby, as shown in FIG. 10, a ridge 54 to be a light waveguide structure is formed.

Next, leaving the resist pattern (not shown) used as the mask, an insulating film composed of SiO₂ is formed again on the entire surface of the substrate by, for example, CVD, vacuum vapor deposition, or sputtering, and the insulating film on the ridge 54 is removed, or lift off, at the same time of resist removal. Thereby, as shown in FIG. 11, insulating film 56 having an opening is formed on the ridge 54.

Next, after sequentially forming a Pd film, a Ta film, and an Au film on the entire surface of the wafer by, for example, vacuum vapor deposition, resist application, lithography, and wet etching or dry etching are performed to form the p-electrode 58. Next, Ti and Au films are sequentially formed in the back surface of the substrate by vacuum vapor deposition to form the n-electrode 60. On the n-electrode 60 on the back surface of the substrate of the blue semiconductor laser 12, the electrically isolated first electrode 62 and second electrode 66 are formed.

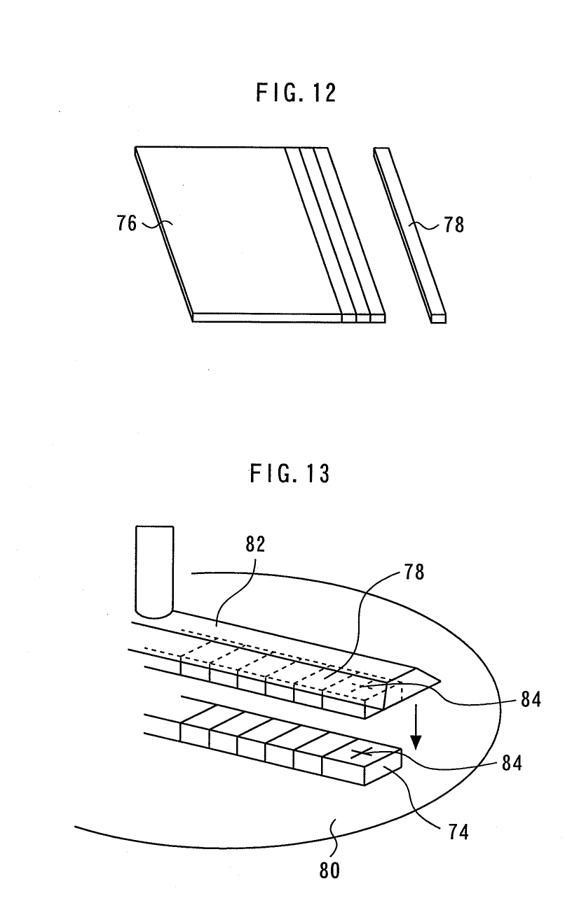

Through the above-described wafer processing, semiconductor chips (second semiconductor chips), a blue semiconductor laser 12, having different wavelength from red semiconductor lasers 14 and infrared semiconductor lasers 16 are formed in lines on the wafer 76. Next, as shown in FIG. 12, the wafer 76 is divided by cleaving to form second bars 78 wherein a plurality of semiconductor chips of the blue semiconductor lasers 12 are arrayed. In the same manner as in the two-wavelength semiconductor lasers 10, coating films are formed on the front and rear ends of the laser.

### Manufacture of Three-Wavelength Semiconductor Laser

First, as shown in FIG. 13, the first bar 74 is placed on the heating table 80 of the bonding device using vacuum contact. Next, the second bar 78 is allowed to vacuum-contact to collets 82. Using an alignment marks 84 formed on the ends of the first bar 74 and the second bar 78, the second bar 78 is moved onto the first bar 74 to allow the laser forming surface of the first bar 74 to face to the back surface of the substrate-of the second bar 78 so that the laser forming surface of the two-wavelength semiconductor laser 10 is aligned to the laser forming surface of the blue semiconductor laser 12 in the same plane. Then, each chip in the first bar 74 is joined to each chip in the second bar 78 to form a third bar 86. At this time, the p-electrode 30 of the red semiconductor laser 14 and the p-electrode 42 of the infrared semiconductor laser 16 are joined to the first electrode 62 and the second electrode 66 of the blue semiconductor laser 12 with solders 68 and 70, respectively. Alternatively, the electrode pattern of the semiconductor lasers may be used as the marks in place of the alignment marks 84.

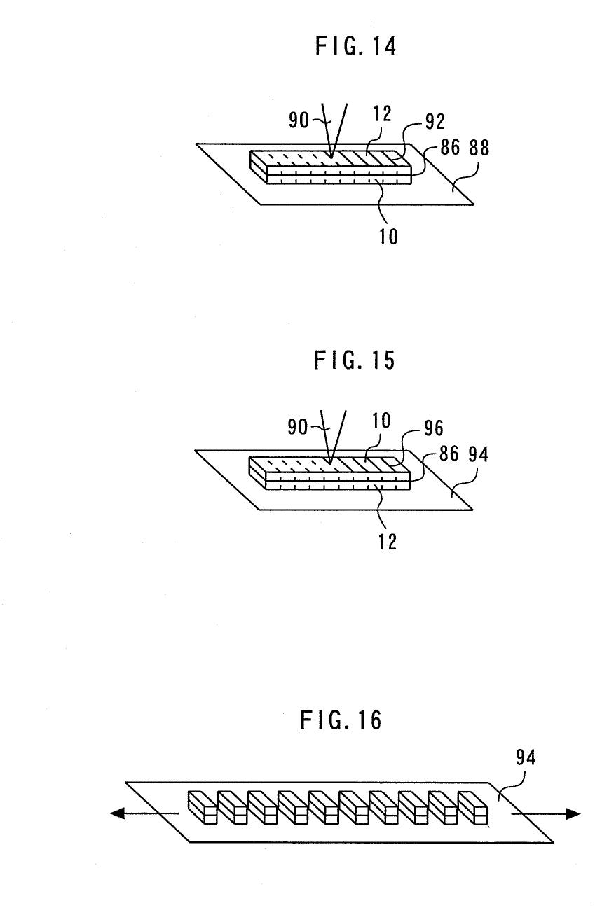

Next, as shown in FIG. 14, the third bar 86 is adhered to the tape 88 with the blue semiconductor laser 12 up. Then, laser beams 90 are radiated to the boundary of chips of the blue semiconductor laser 12 to form a scribe line 92.

Next, as shown in FIG. 15, the third bar 86 is adhered to the tape 94 with the blue semiconductor laser 12 down, and the tape 88 is removed. Then, laser beams 90 are radiated to the boundary of chips of the two-wavelength semiconductor laser 10 (the position facing to the scribe line 92 of the blue semiconductor laser 12) to form a scribe line 96. Next, as shown in FIG. 16, the tape 94 is expanded to divide the third bar 86 along the scribe lines 92 and 96 into chips. Finally, the chips are removed from the tape 94 to complete a three-wavelength semiconductor laser.

### Effect of the First Embodiment

In the first embodiment, after joining a blue semiconductor laser to a two-wavelength semiconductor laser in a bar state, they are divided into chips. Therefore, compared with conventional methods wherein a blue semiconductor laser in a chip state is joined to a two-wavelength semiconductor laser in a chip state, two semiconductor lasers can be precisely aligned. Since a large number of chips can be joined at once, the process can be simplified and productivity can be improved.

By using a laser scriber, no pressure is applied to the bar floating in the space, compared with conventional methods for dividing chips using a cutting saw or a needle-shaped scriber, which scratches the bar. Therefore, the cracking of the chip or the peeling off of the soldered portion can be prevented. Since no cutting saw is used, there is no possibility of moisture invasion into the gap in the boundaries of bars. Furthermore, since the tape is expanded in the state wherein the bars are adhered to the tape, the dispersion of chips is little and the dirt or scratches of the electrode or the end surface of the laser is few. Therefore, according to the manufacturing method of the first embodiment, high reliability can be secured.

### Second Embodiment

In the second embodiment, optical system that can displace the focal point of laser beams in laser scribing is used. Other processes are the same as the process in the first embodiment. The laser scribing process in the second embodiment will be described.

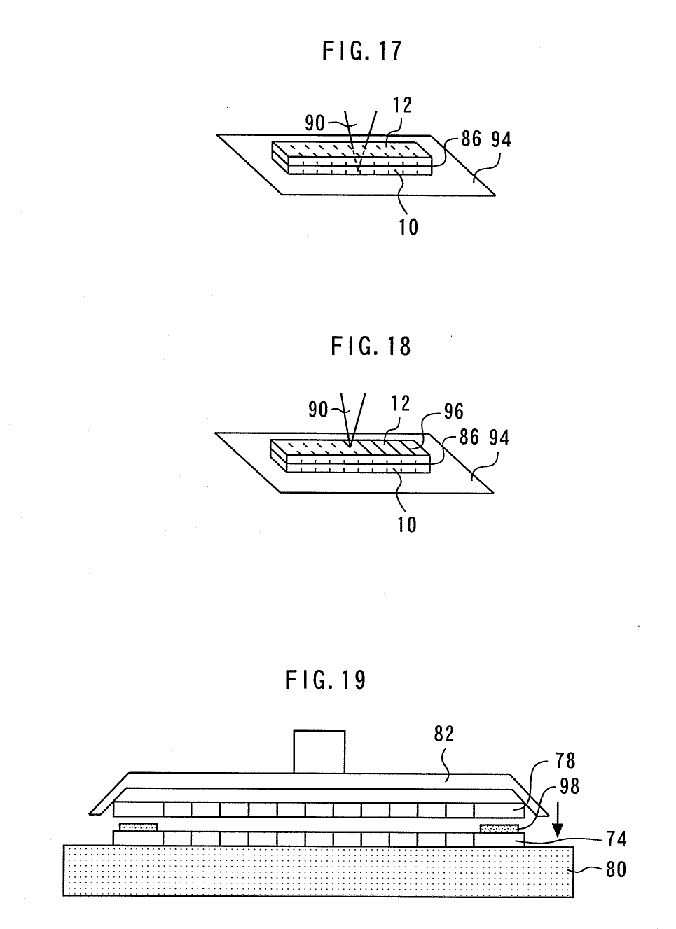

First, as shown in FIG. 17, the tape 94 is adhered to the third bar 86 with the blue semiconductor laser 12 up. Then, laser beams are focused on the two-wavelength semiconductor laser 10, and the laser beams are radiated to the boundary of chips of the two-wavelength semiconductor laser 10 of the third bar 86 to form a scribe line 96. At this time, although the blue semiconductor laser 12 is exposed to laser beams, the blue semiconductor laser 12 is not damaged because the laser beams are out of focus.

Next, as shown in FIG. 18, without rebonding the tape 94, the focal point of the laser beams is displaced to the blue semiconductor laser 12, and the laser beams are radiated on the boundaries of chips of the blue semiconductor laser 12 of the third bar 86 to form the scribe line 92. Thereafter, in the same manner as in the first embodiment, the tape 94 is expanded to divide the bar into chips.

In the second embodiment, since the rebonding of the tape is not required unlike the first embodiment, the process can be simplified.

### Third Embodiment

When the first bar 74 is joined to the second bar 78, if the pressure for bonding is adjusted only by the collet 82, the parallelism and pressure of the both ends of the first bar 74 and the second bar 78 are deviated. In the third embodiment, therefore, spacers 98 are inserted in the both ends of the first bar 74 and the second bar 78 to maintain the distance between the first bar 74 and the second bar 78 constant as shown in FIG. 19. Thereby, the both ends of the first bar 74 and the second bar 78 become parallel, and the deviation of the pressure is eliminated. Other processes and effects are same as those of the first embodiment.

### Fourth Embodiment

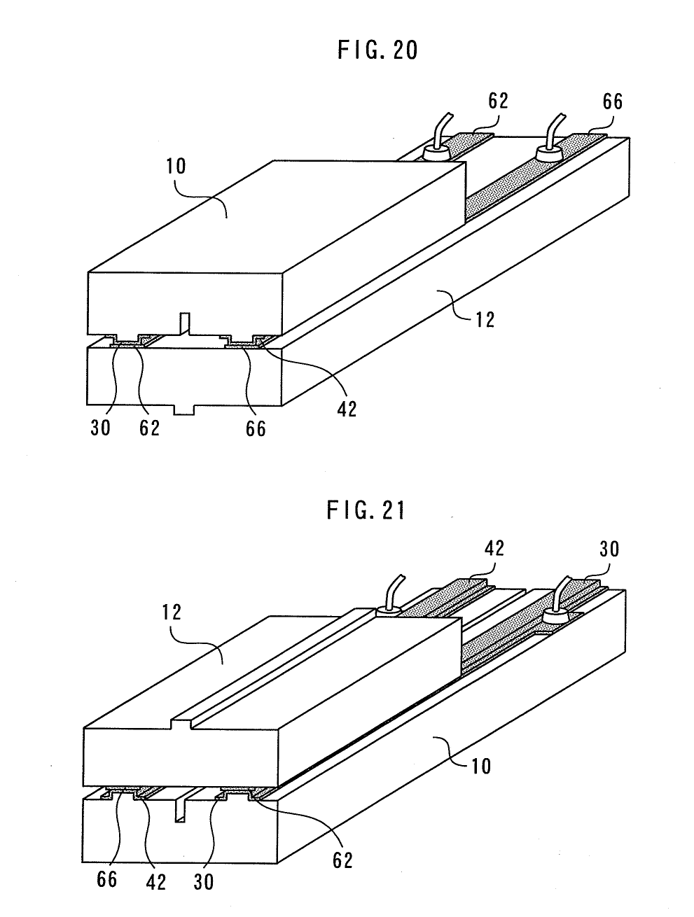

If the cavity length of the two-wavelength semiconductor laser 10 is equalized to the cavity length of the blue semiconductor laser 12, wire bonding to the first electrode 62 and the second electrode 66 has to be performed in the narrow gap region between the blue semiconductor laser 12 and the two-wavelength semiconductor laser 10. In the fourth embodiment, therefore, the cavity length of the two-wavelength semiconductor laser 10 is made shorter than the cavity length of the blue semiconductor laser 12 as shown in FIG. 20, and a wire bonding region is provided in the substrate side of the blue semiconductor laser 12. Then, wire bonding is performed to the first electrode 62 and the second electrode 66 of the blue semiconductor laser 12, respectively. Thereby, wire bonding can be easily performed, and productivity is improved. If plated layers are formed on the first electrode 62 and the second electrode 66, the current capacity is increased, and the adhesiveness of wire bonding is improved.

### Fifth Embodiment

In the fifth embodiment, as shown in FIG. 21, the cavity length of the two-wavelength semiconductor laser 10 is made longer than the cavity length of the blue semiconductor laser 12, and a wire bonding region is provided in the ridge side of the two-wavelength semiconductor laser 10. Then, wire bonding is performed to the p-electrode 30 of the red semiconductor laser 14 and the p-electrode 42 of the infrared semiconductor laser 16, respectively. In this case, pad regions for wire bonding have to be formed on the p-electrodes 30 and 42. Thereby, the equivalent effects as the effects of the fourth embodiment can be obtained.

Although an example of a three-wavelength laser of blue, red, and infrared has been shown in the embodiments described above, the present invention can also be applied to other multiple-wavelength lasers.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2009-012995, filed on Jan. 23, 2009 including specification, claims, drawings and summary, on which the Convention priority of the present application is based, are incorporated herein by reference in its entirety.

1. A method for manufacturing a multiple-wavelength semiconductor laser comprising:
forming a first bar having a plurality of arrayed first semiconductor chips, wherein at least two semiconductor lasers producing light having different wavelengths are monolithically formed;
forming a second bar having a plurality of arrayed second semiconductor chips, wherein a semiconductor laser producing light having a different wavelength from the light produced by the semiconductor lasers of said first semiconductor chips is formed;
forming a third bar by locating a laser-forming surface of said first bar facing a back surface of said second bar, and joining respective first semiconductor chips in said first bar to respective second semiconductor chips in said second bar;
forming scribe lines by irradiating boundaries of said first semiconductor chips and boundaries of said second semiconductor chips, respectively, with laser beams; and
dividing said third bar along said scribe lines into respective chips.

2. The method for manufacturing a multiple-wavelength semiconductor laser according to claim 1, including bonding a tape to said third bar when said third bar is divided, and stretching said tape to divide said third bar along said scribe line into respective chips.

3. The method for manufacturing a multiple-wavelength semiconductor laser according to claim 2, including
bonding said tape to said third bar when said scribe line is formed;
focusing the laser beams on boundaries of either said first semiconductor chips or said second semiconductor chips in said third bar to form said scribe line; and
without rebonding said tape, displacing focus points of the laser beams, and focusing the laser beams on boundaries of other semiconductor chips in said third bar to form said scribe line.

4. The method for manufacturing a multiple-wavelength semiconductor laser according to claim 1, wherein when said first bar is bonded to said second bar, inserting spacers at opposite ends of said first bar and said second bar to maintain a distance between said first bar and said second bar.

5. The method for manufacturing a multiple-wavelength semiconductor laser according to claim 1, including forming a two-wavelength semiconductor laser including a red semiconductor laser, producing red light, and an infrared semiconductor laser, producing infrared light, in said first semiconductor chip, and forming a blue semiconductor laser, producing blue light, in said second semiconductor chip.

6. The method for manufacturing a multiple-wavelength semiconductor laser according to claim 5, including
making cavity length of said two-wavelength semiconductor laser shorter than cavity length of said blue semiconductor laser;
forming a p-electrode of said red semiconductor laser and a p-electrode of said infrared semiconductor laser on the laser-forming surface of said two-wavelength semiconductor laser,
forming a first electrode and a second electrode electrically isolated from each other on the back surface of said blue semiconductor laser;
when said third bar is formed, aligning a laser-beam outgoing surface of said two-wavelength semiconductor laser to be co-planar with a laser-beam outgoing surface of said blue semiconductor laser, and joining said p-electrode of said red semiconductor laser and said p-electrode of said infrared semiconductor laser to said first electrode and to said second electrode of said blue semiconductor laser, respectively; and
wire bonding each of said first electrode and said second electrode of said blue semiconductor laser.

7. The method for manufacturing a multiple-wavelength semiconductor laser according to claim 5, including
making cavity length of said two-wavelength semiconductor laser longer than cavity length of said blue semiconductor laser;
forming a p-electrode of said red semiconductor laser and a p-electrode of said infrared semiconductor laser on the laser forming surface of said two-wavelength semiconductor laser;
forming a first electrode and a second electrode electrically isolated from each other on the back surface of said blue semiconductor laser;
when said third bar is formed, aligning a laser-beam outgoing surface of said two-wavelength semiconductor laser to be co-planar with a laser-beam outgoing surface of said blue semiconductor laser, and joining said p-electrode of said red semiconductor laser and said p-electrode of said infrared semiconductor laser to said first electrode and to said second electrode of said blue semiconductor laser, respectively; and
wire bonding each of said p-electrode of said red semiconductor laser and said p-electrode of said infrared semiconductor laser.
